(19) United States
(12) Patent Application Publication
(10) Pub. No.: US 2010/0073206 A1
(43) Pub. Date: Mar. 25, 2010

(54) ANALOG-TO-DIGITAL CONVERSION CIRCUITS AND METHOD FOR CALIBRATING THEREOF

(75) Inventor: Zwei-Mei Lee, Taoyuan County (TW)

Correspondence Address: THOMAS, KAYDEN, HORSTEMEYER & RISLEY, LLP, 600 GALLERIA PARKWAY, S.E., STE 1500, ATLANTA, GA, 30339-5994, US

(73) Assignee: MEDIATEK INC., Hsin-Chu (TW)

(21) Appl. No.: 12/555,961

(22) Filed: Sep. 9, 2009

Related U.S. Application Data
(63) Continuation-in-part of application No. 12/236,755, filed on Sep. 24, 2008.

(51) Int. Cl. H03M 1/10

(52) U.S. Cl. 341/118; 341/120

(57) ABSTRACT

An analog-to-digital conversion circuit is provided and includes an input unit, at least one analog-to-digital converter, and a processing unit. The input unit receives an analog input signal and outputs an analog output signal. A first reference signal is injected into the input unit, and the analog output signal is related to the first reference signal. The at least one analog-to-digital converter receives the analog output signal and converts the analog output signal to a digital output signal. The processing unit receives the digital output signal and performs correlation computation on the digital output signal with a second reference signal to generate a calibration parameter.

### CROSS REFERENCE TO RELATED APPLICATIONS

This application is a Continuation-In-Part of pending U.S. patent application Ser. No. 12/236,755, filed Sep. 24, 2008, and entitled “TRACK AND HOLD AMPLIFIERS AND ANALOG TO DIGITAL CONVERTERS”.

### BACKGROUND OF THE INVENTION

1. Field of the Invention

The invention relates to an analog-to-digital conversion circuit, and more particularly to an analog-to-digital conversion circuit having background analog-to-digital conversion gain calibration, and a calibration method thereof.

2. Description of the Related Art

A conventional time-interleaved analog-to-digital conversion circuit has a plurality of analog-to-digital channels for high-speed analog-to-digital conversion. As shown in FIG. 6, a conventional time-interleaved analog-to-digital conversion circuit 6 comprises a sample-and-hold amplifier (or a track-and-hold amplifier) 60, a plurality of analog-to-digital converters (ADC) 61₁-61_{N}, and a multiplexer 62. The combination of the sample-and-hold amplifier 60 and one of the analog-to-digital converters 61₁-61_{N} functions as one analog-to-digital channel. The sample-and-hold amplifier 60 samples an input analog signal Ain60 and generates an analog output signal Aout60. The analog-to-digital converters 61₁-61_{N} individually perform the analog-and-digital conversion for the analog output signal Aout60 to generate digital signals D₁-D_{N}. The multiplexer 62 receives the digital signals D₁-D_{N} and sequentially outputs the digital signals D₁-D_{N}. Thus, with the increase in the number of analog-to-digital channels, the analog-to-digital conversion speed can be increased. However, gain mismatch errors among the digital signals D₁-D_{N} caused by mismatch among the analog-to-digital channels degrade the performance and the conversion linearity of the time-interleaved analog-to-digital conversion circuit 6.

Thus, it is desired to provide a time-interleaved analog-to-digital conversion circuit in which errors such as gain mismatch errors can be compensated.

### BRIEF SUMMARY OF THE INVENTION

An exemplary embodiment of an analog-to-digital conversion circuit comprises an input unit, at least one analog-to-digital converter, and a processing unit. The input unit receives an analog input signal and outputs an analog output signal. A first reference signal is injected into the input unit, and the analog output signal is related to the first reference signal. The at least one analog-to-digital converter receives the analog output signal and converts the analog output signal to a digital output signal. The processing unit receives the digital output signal and performs correlation computation on the digital output signal with a second reference signal to generate a calibration parameter.

Another exemplary embodiment of a time-interleaved analog-to-digital conversion circuit with background calibration comprises an input unit, a plurality of analog-to-digital converters, and a processing unit. The input unit receives an analog input signal and outputs an analog output signal. A reference signal is injected into the input unit, and the analog output signal is related to the reference signal and the analog input signal. The analog-to-digital converters receive the analog output signal and respectively convert the analog output signal to digital output signals according to a plurality of timing clocks. The processing unit receives at least one of the digital output signals, and extracts a calibration parameter for analog-to-digital conversion gain compensation according to the digital output signal.

An exemplary embodiment of a method for calibrating an analog-to-digital conversion circuit comprises steps of providing an analog input signal and a first reference signal; generating an analog output signal according to the analog input signal and the first reference signal; converting the analog output signal into at least one digital output signal; and performing a correlation computation on the digital output signal to generate a calibration parameter.

A detailed description is given in the following embodiments with reference to the accompanying drawings.

### BRIEF DESCRIPTION OF THE DRAWINGS

The invention can be more fully understood by reading the subsequent detailed description and examples with references made to the accompanying drawings, wherein:

FIG. 1 shows a simple track and hold amplifier;

FIG. 2 shows an analog to digital converter according to an embodiment of the invention;

FIGS. 3A and 3B show the waveforms of the signals Φ₁, Φ₁ₐ, and Φ₂;

FIG. 4 shows a track and hold amplifier according to another embodiment of the invention;

FIG. 5 shows a track and hold amplifier according to another embodiment of the invention;

FIG. 6 shows a conventional time-interleaved analog-to-digital conversion circuit;

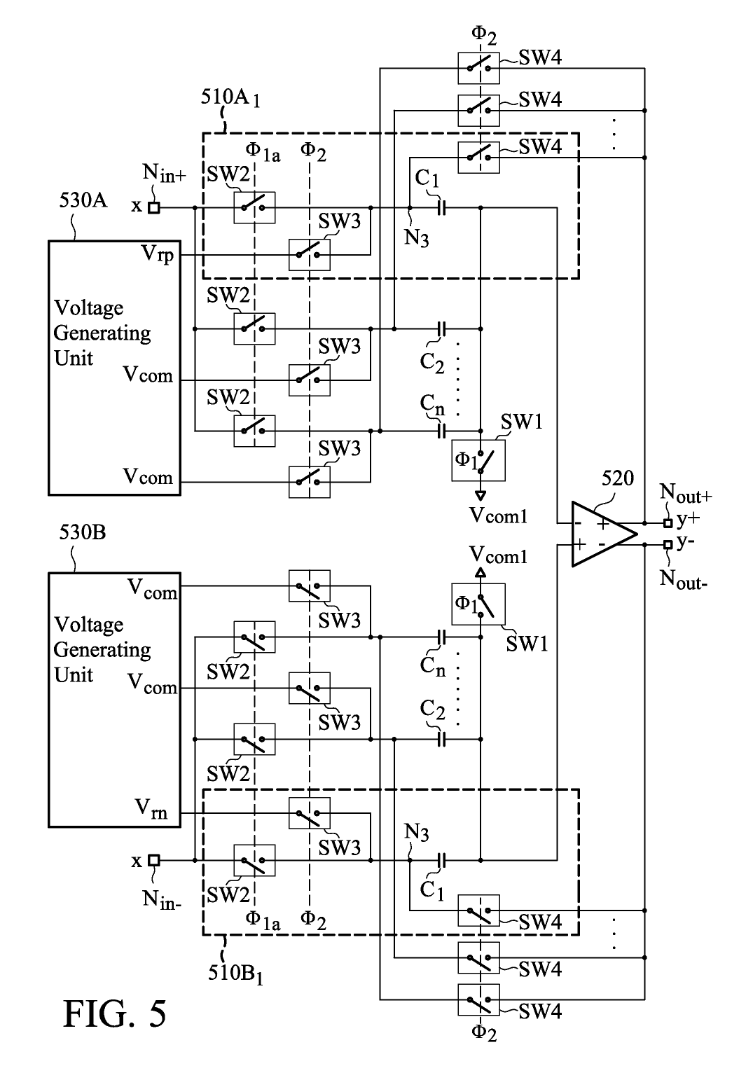

FIG. 7 shows an exemplary embodiment of an analog-to-digital conversion circuit;

FIG. 8 shows the detailed circuit of the analog-to-digital conversion circuit in FIG. 7;

FIG. 9 shows the operation of the input unit of the analog-to-digital conversion circuit in FIG. 7 during the tracking period;

FIG. 10 shows the operation of the input unit of the analog-to-digital conversion circuit in FIG. 7 during the holding period;

FIG. 11 shows waveform characteristics of the random sequence qₐ, and q_{b};

FIG. 12 shows another exemplary embodiment of an analog-to-digital conversion circuit;

FIG. 13 shows another exemplary embodiment of the input unit of the analog-to-digital conversion circuit in FIG. 7;

FIG. 14 shows another exemplary embodiment of the input unit of the analog-to-digital conversion circuit in FIG. 7;

FIG. 15 is a flow chart of an exemplary embodiment of a method for compensating for gain mismatch error in an analog-to-digital conversion circuit.

### DETAILED DESCRIPTION OF THE INVENTION

The following description is of the best-contemplated mode of carrying out the invention. This description is made for the purpose of illustrating the general principles of the invention and should not be taken in a limiting sense. The scope of the invention is best determined by reference to the appended claims.

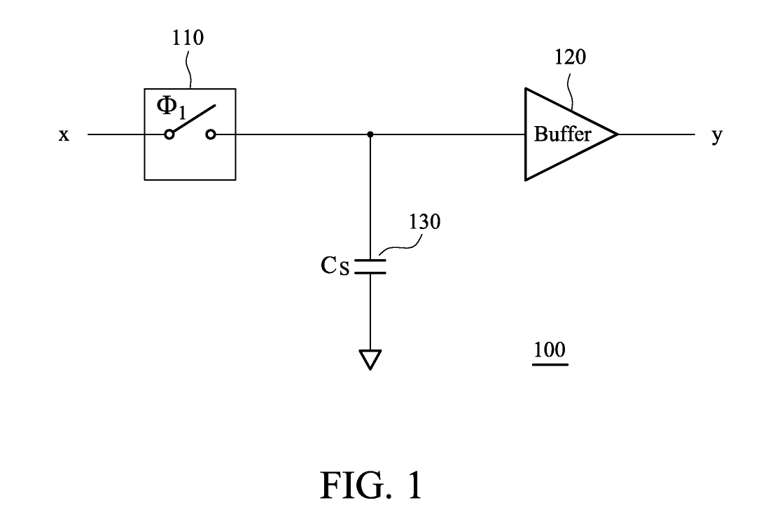

FIG. 1 shows a simple track and hold amplifier 100. The track and hold amplifier 100 comprises a switch 110, a buffer 120 and a capacitor 130, wherein the switch 110 is controlled by a signal Φ₁. During a track mode (i.e. the switch 110 is turned on), an analog input signal x is received by an input of the track and hold amplifier 100, and is then transferred to the capacitor 130 which is coupled to an input of the buffer 120. During a hold mode (i.e. the switch 110 is turned off), the capacitor 130 is de-coupled from the input of the track and hold amplifier 100 thereby holding a charged voltage across the capacitor 130. Then, an output signal y of the buffer 120 is transferred to the subsequent circuits of an analog to digital converter. In FIG. 1, a value of the capacitor 130 is Cₛ.

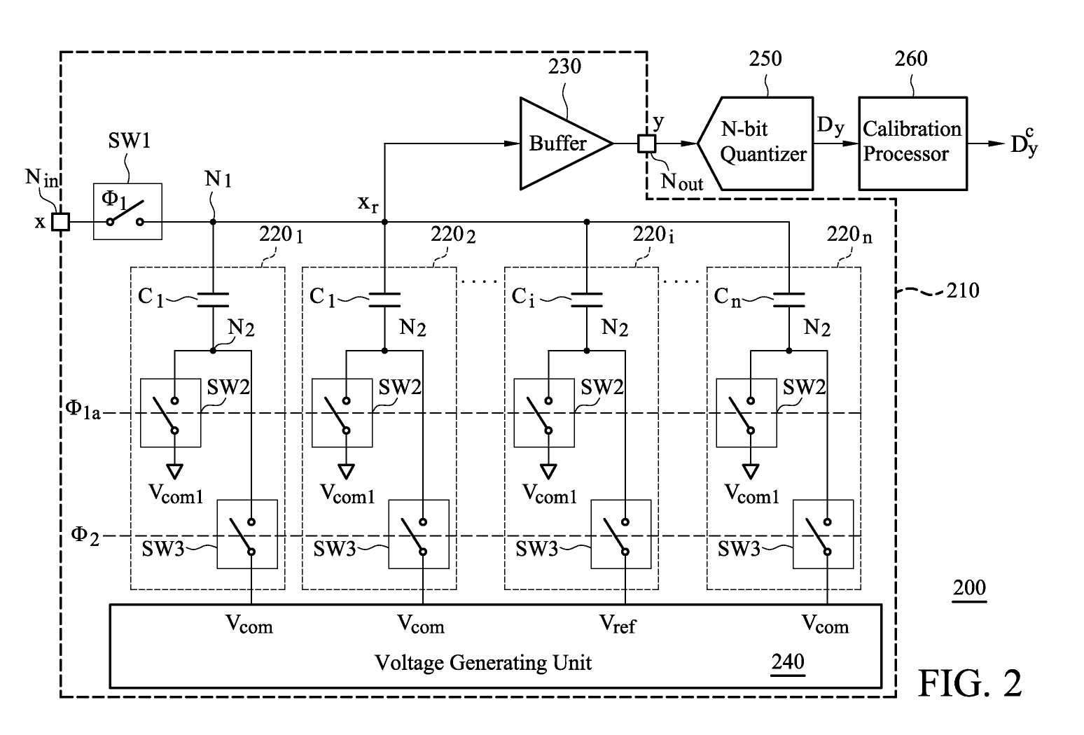

FIG. 2 shows an analog to digital converter 200 according to an embodiment of the invention. The analog to digital converter 200 comprises a track and hold amplifier 210, an N-bit quantizer 250 and a calibration processor 260. The track and hold amplifier 210 tracks and holds an analog input signal x to generate a sampled signal y. Next, the N-bit quantizer 250 quantizes the sampled signal y to generate an N-bit digital signal D_{y} Finally, the calibration processor 260 receives the quantized signal D_{y} and calibrates its nonlinearity caused by the track and hold amplifier 210 to generate a digital output signal D_{y}^{c}.

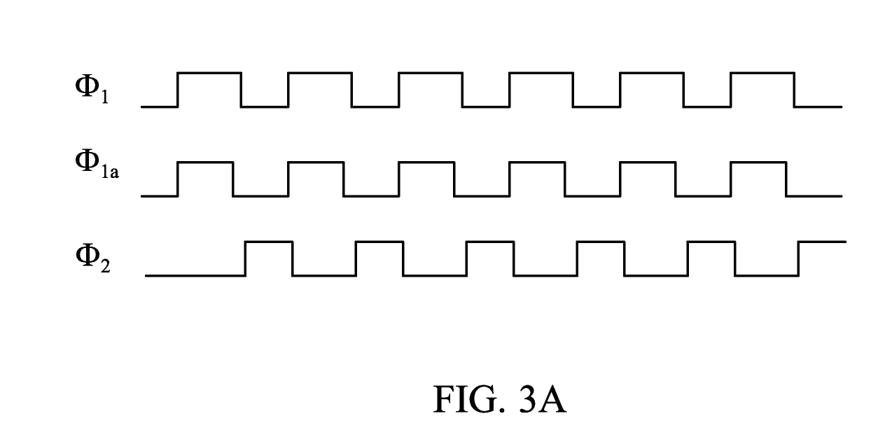

As shown in FIG. 2, the track and hold amplifier 210 is an open-loop circuit, which comprises a switch SW1, a plurality of switching circuits 220₁-220ₙ, a buffer 230 and a voltage generating unit 240. The switch SW1 is coupled between an input node Nᵢₙ for receiving the analog input signal x and a node N₁, and the switch SW1 is controlled by a signal Φ₁. The buffer 230 is coupled between the node N₁ and an output node Nₒᵤₜ. In some embodiments, the buffer 230 is an amplifier with gain. Each of the switching circuits 220₁-220ₙ, is coupled between the node N₁ and the voltage generating unit 240. The switching circuits 220₁-220ₙ may have similar architectures and each switching circuit may comprise a capacitor and two switches. Using the switching circuit 220₁as an example, the switching circuit 220₁ comprises a capacitor C₁ coupled between the node N₁ and a node N₂, a switch SW2 coupled between the node N₂ and a common node V_{com1} and a switch SW3 coupled between the node N₂ and the voltage generating unit 240. The voltage generating unit 240 selectively provides a common signal V_{com} and a reference signal V_{ref} to the switching circuits 220₁-220ₙ, wherein the reference signal V_{ref} may be any signal independent from the analog input signal x and the common signal V_{com}. Furthermore, a voltage of the common signal V_{com} may either be equal to a voltage provided by the common node V_{com1} or not. Furthermore, in track and hold amplifier 210, each of the switches SW2 is controlled by a signal Φ₁ₐ and each of the switches SW3 is controlled by a signal Φ₂, wherein the switches SW2 and the switches SW3 are not turned on simultaneously. Refer to FIGS. 3A and 3B for the waveforms illustrating different embodiments of phase relation between the signals Φ₁, Φ₁ₐ and Φ₂, wherein the signals Φₐ and Φ₂ in FIG. 3B are non-overlap clock signals.

Referring to FIG. 2 and FIG. 3A together, when the signal Φ₁ is at a high level voltage (a track mode), the switches SW1 and SW2 are turned on and the switches SW3 are turned off. During the track mode, a signal xᵣ of the node N₁ is equal to the analog input signal x. When the signal Φ₂ is at a high level voltage (a hold mode), the switches SW1 and SW2 are turned off and the switches SW3 are turned on. During the hold mode, the voltage generating unit 240 provides the reference signal V_{ref} to the switching circuit 220ᵢ and the common signal V_{com} to the other switching circuits (i.e. the switching circuits 220₁-220ₙ except for the switching circuit 220ᵢ), as shown in FIG. 2, the signal xᵣ may be calculated as the following equation (1):

$${x}_{r} = x - {V}_{ref} \times \frac{{C}_{i}}{{\sum }_{k = 1}^{n} {C}_{k}} . \qquad ( 1 )$$

Next, the signal xᵣ may be rewritten as the following equation (2):

$${x}_{r} = x - {V}_{ref} \times \frac{{C}_{i}}{{\sum }_{k = 1}^{n} {C}_{k}} = x - {q}_{1} \times R \times \frac{{C}_{i}}{{\sum }_{k = 1}^{n} {C}_{k}} = x - {q}_{1} - {R}_{i} , \qquad ( 2 )$$

where q₁ is a sequence independent from the analog input signal x, which may be binary-valued, R is a predetermined value and

$${R}_{i} = R \times \frac{{C}_{i}}{{\sum }_{k = 1}^{n} {C}_{k}} .$$

Moreover, in this invention, a summing capacitor value of the capacitors

$$( {\sum }_{k = 1}^{n} {C}_{k} )$$

is equal to the value of the capacitor 130 (Cₛ) as shown in FIG. 1. In one embodiment, the capacitors C1-Cn may not have the same capacitances in order to obtain randomization to calibrate nonlinearity. For example, each capacitor may have one of the capacitances which are a unit capacitance Cᵤₙᵢₜ to the power of 2, i.e. Cᵤₙᵢₜ, Cᵤₙᵢₜ², Cᵤₙᵢₜ⁴ and so on. Next, the buffer 230 receives the signal xᵣ to generate the sampled signal y. Because of the buffer 230 is nonlinear, the sampled signal y may be expressed as a polynomial shown in the following equation (3):

y=a₀+a₁×xᵣ+a₂×xᵣ²+a₃×xᵣ³+ . . . (3).

If input and output characteristics of the buffer 230 are monotonic, the signal xᵣ may be expressed as the following equation (4):

xᵣ=b₀+b₁×y+b₂×y²+b₃×y³+ . . . (4).

Next, the N-bit quantizer 250 quantizes the sampled signal y to generate the N-bit digital signal D_{y}, and the calibration processor 260 calibrates the N-bit digital signal D_{y} to generate the digital output signal D_{y}^{c} which is an estimate of the signal xᵣ in digital domain and may be expressed as the following equation (5):

D_{y}^{c}=\hat{b}₀+\hat{b}₁×D_{y}+\hat{b}₂×D_{y}²+\hat{b}₃×D_{y}³+ . . . (5).

Because the digital output signal D_{y}^{c} closely approximates the signal xᵣ, the signal xᵣ may be rewritten as the following equation (6) according to the equations (4) and (5):

xᵣ=D_{y}^{c}+(b₀−\hat{b}₀)+(b₁−\hat{b}₁)×D_{y}+(b₂−\hat{b}₂)×D_{y}²+(b₃−\hat{b}₃)×D_{y}³+ . . . (6).

Next, the expectation values of the both sides of the equation (6) correlated with the value q may be calculated as the following equation (7):

E{q₂×xᵣ}=E{q₂×└D_{y}^{c}+(b₀−\hat{b}₀)+(b₁−\hat{b}₁)×D_{y}+(b₂−\hat{b}₂)×D_{y}²+(b₃−\hat{b}₃)×D_{y}³+ . . . ┘} (7).

where q₂ may have the same waveform as q₁, and may be zero-mean, binary-valued sequence.
Next, the equation (7) may be rewritten as the following equation (8):

Rᵢ≈W_{ic}^{I}+Δb₁×Wᵢ^{I}+Δb₂×Wᵢ^{II}+Δb₃×Wᵢ^{III}+Δb₄×Wᵢ^{IV}+ . . . (8)
where
   Δbₖ=bₖ−\hat{b}ₖ
   W_{ic}^{I}=E{q₂×D_{y}^{c}}, and
   Wᵢ^{I}=E{q₂×D_{y}}, Wᵢ^{II}=E{q₂×D_{y}²}, . . .

Furthermore, assuming that the voltage generating unit 240 provides the reference signal V_{ref} to the switching circuit 220ⱼ, and not the switching circuit 220ᵢ, and provides the common signal V_{com} to the other switching circuits (i.e. the switching circuits 220₁-220ₙ except for the switching circuit 220ⱼ) during the hold mode, Rⱼ may be calculated and expressed as the following equation (9):

Rⱼ≈W_{jc}^{I}+Δb₁×Wⱼ^{I}+Δb₂×Wⱼ^{II}+Δb₃×Wⱼ^{III}+Δb₄×Wⱼ^{IV}+ . . . (9)

Moreover, assuming that the voltage generating unit 240 provides the reference signal V_{ref} to both the switching circuits 220₁ and 220ⱼ, and provides the common signal V_{com} to the other switching circuits (i.e. the switching circuits 220₁-220ₙ except for the switching circuits 220ᵢ and 220ⱼ) during the hold mode, Rₜ may be calculated and expressed as the following equation (10):

Rₜ≈W_{tc}^{I}+Δb₁×Wₜ^{I}+Δb₂×Wₜ^{II}+Δb₃×Wₜ^{III}+Δb₄×Wₜ^{IV}+ . . . (10).

The following equation (11) may be calculated according to the equations (8), (9) and (10) due to linearity:

Rₜ−(Rᵢ+Rⱼ)=0≈H_{tc}^{I}+Δb₁×Hₜ^{I}+Δb₂×Hₜ^{II}+Δb₃×Hₜ^{III}+Δb₄×Hₜ^{IV}+ . . . (11)
where
   H_{tc}^{I}=W_{tc}^{I}−(W_{ic}^{I}+W_{jc}^{I}),
   Hₜ^{I}=Wₜ^{I}−(Wᵢ^{I}+Wⱼ^{I}),
   Hₜ^{II}=Wₜ^{II}−(Wᵢ^{II}+Wⱼ^{II}),
      . . .
         As described above, any Rₜ may be obtained by selecting two different switching circuits from the switching circuits 220₁-220ₙ. Then, the calibration processor 260 may obtain the difference Δb by solving the simultaneous and different equations (11) to calibrate nonlinearity caused by the buffer 230. For example, solving two different equations (11) may obtain Δb₂ and Δb₃ thus compensating nonlinearity caused by the second order and the third order factors of the above equations.

Furthermore, the voltage generating unit 240 provides the reference signal V_{ref} to the switching circuits 220₁-220ₙ according to a sequence. In one embodiment, the voltage generating unit 240 may sequentially provide the reference signal V_{ref} to the switching circuits 220₁-220ₙ during a period of time T which comprises a plurality of sub-time periods. For example, the voltage generating unit 240 may provide the reference signal V_{ref} to the switching circuit 220₁, during a sub-time period t₁, which may comprise a plurality of clock cycles of the signal Φ₂ shown in FIG. 3A or 3B, and provides the common signal V_{com} to the switching circuits 220₂-220ₙ. Next, the voltage generating unit 240 may provide the reference signal V_{ref} to the switching circuit 220₂ during a sub-time period t₂, and provides the reference signal V_{ref} to the switching circuit 220₃ during a sub-time period t₃ and so on, where the length of t₁ to tₙ may be the same. In another embodiment, the voltage generating unit 240 may provide the reference signal V_{ref} to the switching circuits 220₁-220ₙ during the period of time T. For example, the voltage generating unit 240 provides the reference signal V_{ref} to the switching circuit 220₃ during the sub-time period t₁, to the switching circuit 220ₙ during the sub-time period t₂, and to the switching circuit 220₁ during the sub-time period t₃. In another embodiment, the voltage generating unit 240 may simultaneously provide the reference signal V_{ref} to more than one switching circuit during a sub-time period. For example, the voltage generating unit 240 provides the reference signal V_{ref} to the switching circuits 220₁ and 220₂ during the sub-time period t₁ and to the switching circuits 220₃ and 220₄ during the sub-time period t₂.

In this invention, a sequence or amount of the reference signal V_{ref} provided to the switching circuits of a track and hold amplifier may be determined or adjusted according to accuracy and design of an A/D converter, and may be the same or not. Furthermore, the period, duty cycle or amplitude of the reference signal V_{ref} may also be determined or adjusted, and may be the same or not. Moreover, in one embodiment, all capacitors of a track and hold amplifier may have the same capacitances or not.

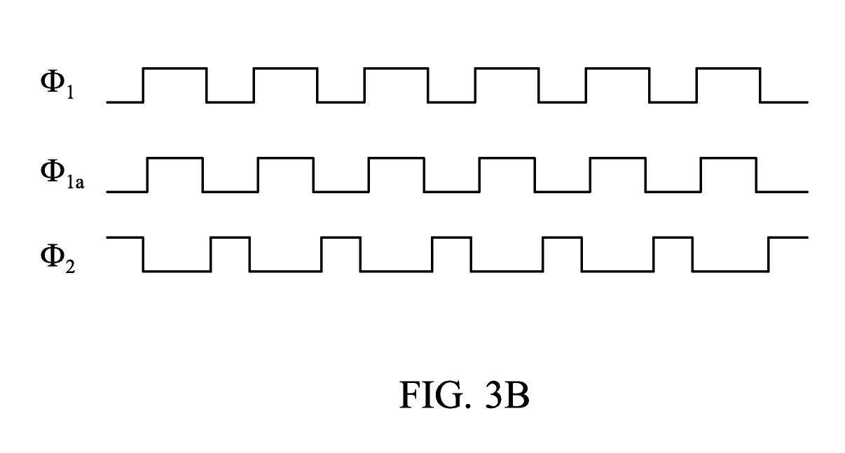

FIG. 4 shows a track and hold amplifier 400 according to another embodiment of the invention. The track and hold amplifier 400 is a closed-loop circuit, which comprises a switch SW1, a plurality of switching circuits, an amplifier 420 and a voltage generating unit 430. The switch SW1 is coupled between a common node and an inverting input node of the amplifier 420, and the switch SW1 may be controlled by the signal Φ₁ shown in FIG. 3A or 3B. Each of the switching circuits is coupled between a node Nᵢₙ for receiving the analog input signal x and the inverting input node of the amplifier 420. The switching circuits may have similar architectures and each may comprise a capacitor and three switches. Using the switching circuit 410₁, as an example, the switching circuit 410₁, comprises a capacitor C₁, coupled between a node N₃ and the inverting input node of the amplifier 420, a switch SW2 coupled between the node Nᵢₙ and the node N₃, a switch SW3 coupled between the node N₃ and the voltage generating unit 430, and a switch SW4 coupled between the node N₃ and an output node Nₒᵤₜ.

In the track and hold amplifier 400, each of the switches SW2 may be controlled by the signal Φ₁ₐ as shown in FIG. 3A or 3B, and each of the switches SW3 and SW4 may be controlled by the signal Φ₂ as shown in FIG. 3A or 3B, hence the switches SW3 and SW4 may be synchronous. In addition, a non-inverting input node of the amplifier 420 is coupled to the common node, and an output of the amplifier 420 is coupled to the output node Nₒᵤₜ. Similarly, the voltage generating unit 430 selectively provides the common signal V_{com} and the reference signal V_{ref} to the switching circuits, and may provide the reference signal V_{ref} to the switching circuits according to the sequence as described previously. A voltage of the common signal V_{com} may either be equal to a voltage provided by the common node V_{com1} or not.

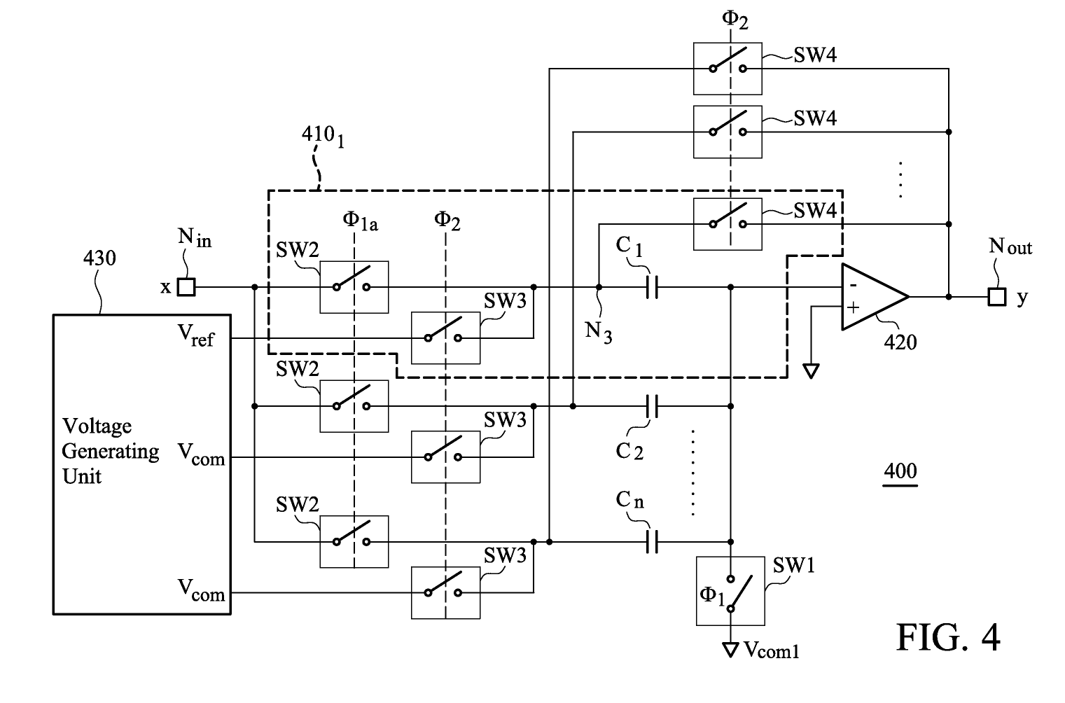

FIG. 5 shows a track and hold amplifier according to another embodiment of the invention. The track and hold amplifier is a closed-loop circuit comprising two switches SW1, a plurality of switching circuits, an amplifier 520 and two voltage generating unit 530A and 530B. Compared to the amplifier 420 of FIG. 4, the amplifier 520 is a fully differential amplifier. Furthermore, using the switching circuits 510A₁ and 510B₁ as illustration, the switching circuit 510A₁ is coupled between a node Nᵢₙ₊ for receiving the analog input signal x and the inverting input node of the amplifier 520, and the switching circuit 510B₁ is coupled between a node Nᵢₙ₋ for receiving the analog input signal x and the non-inverting input node of the amplifier 520. In addition, the non-inverting and inverting outputs of the amplifier 520 are coupled to the output nodes Nₒᵤₜ₊ and Nₒᵤₜ₋, respectively. The voltage generating unit 530A selectively provides the common signal V_{com} and a reference signal Vᵣₚ to the switching circuits coupled to the node Nᵢₙ₊, and the voltage generating unit 530B selectively provides the common signal V_{com} and a reference signal Vᵣₙ to the switching circuits coupled to the node Nᵢₙ₋. In this embodiment, the track and hold amplifier may track and hold the analog input signal x to generate two sampled signals y+ and y−. Then, a successional quantizer (not shown) may quantize the sampled signal y+ or y− to generate a digital signal D_{y}, as described above.

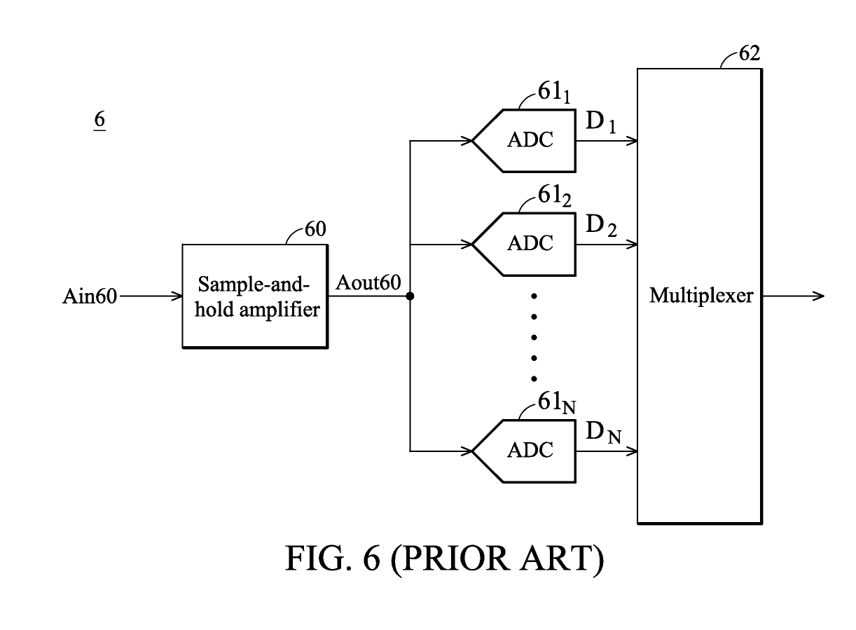

Moreover, in an exemplary embodiment of an analog-to-digital conversion circuit in FIG. 7, an analog-to-digital conversion circuit 7 comprises an input unit 70, a plurality of analog-to-digital converters (ADC) 71₁-71_{N}, a processing unit 72, and a multiplexer 73, wherein N is a positive integer. The input unit 70 receives an analog input signal Ain70 and outputs an analog output signal Aout70. In one embodiment, the input unit 70 operates like a sample-and-hold amplifier or a track-and-hold amplifier. Especially, a first reference signal Ta is injected into the input unit 20, and, thus, the analog output signal Aout70 is related to the first reference signal Ta and the analog input signal Ain70. The analog-to-digital converters 71₁-71_{N} receive the analog output signal Aout70 and individually perform analog-to-digital conversion to the analog output signal Aout70 according to different timing clocks to generate digital output signal Dout70₁-Dout70_{N}. One signal path from the input unit 70 to one of the analog-to-digital converters 71₁-71_{N} functions as one analog-to-digital channel. Thus, there are N analog-to-digital channels in the analog-to-digital conversion circuit 7. Since the gains of the analog-to-digital converters 71₁-71_{N} may be different due to fabrication errors, gain mismatch error may occur among the digital output signals Dout70₁-Dout70_{N} in the N analog-to-digital channels.

To reduce the gain mismatch error occurring among the digital output signals Dout70₁-Dout70_{N} in the analog-to-digital channels, the processing unit 72 receives the digital output signals Dout70₁-Dout70_{N} and extracts calibration parameters respectively from the digital output signals Dout70₁-Dout70_{N}. The processing unit 72 compensates for the gain mismatch errors of the digital output signals Dout70₁-Dout70_{N} according to the calibration parameters. After compensation for the gain mismatch errors, the processing unit 72 generates a plurality of final output signals Dout71₁-Dout71_{N} respectively corresponding to the digital output signals Dout70₁-Dout70_{N}. The multiplexer 73 receives the final output signals Dout71₁-Dout71_{N} and selectively outputs the final output signals Dout71₁-Dout71_{N}.

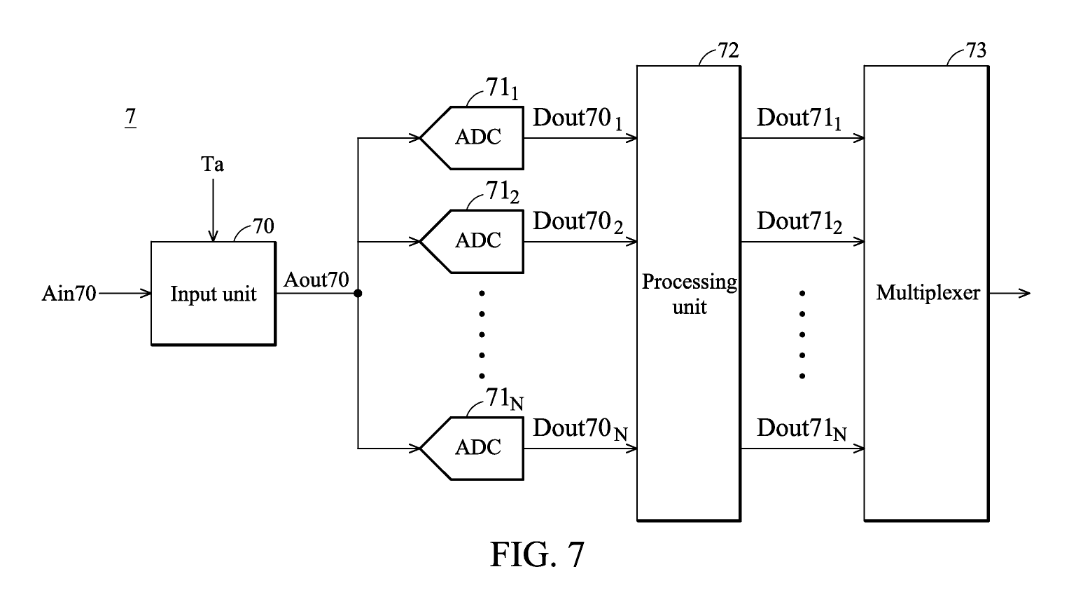

In the embodiment, the input unit 70 is implemented by a track-and-hold amplifier circuit, as shown in FIG. 8. The track-and-hold amplifier circuit comprises switches 700-702, capacitors Cs70 and Cd70, and a buffer 703. The switch 700 is coupled between an input node IN70, which receives the analog input signal Ain70, and a node N70 and is controlled by a control signal Φ71. The capacitor Cd70 is coupled between the node N70 and a node N71. The switch 701 has a first terminal coupled to the node N71 and a second terminal receiving the first reference signal Ta and controlled by a control signal Φ72. In the embodiment, the control signal Φ72 is only enabled in the hold phase, and an active period of the control signal Φ71 does not overlap an active period of the second control signal Φ72. The switch 702 is coupled between the node N71 and a third terminal, such as the ground GND shown in FIG. 8, and is controlled by the control signal Φ71. The capacitor Cs70 is coupled between the node N70 and the third terminal. The buffer 703 is coupled to the node N70 and is used to output the analog output signal Aout70.

Moreover, referring to FIG. 8, the processing unit 72 comprises a plurality of correlators 720₁-720_{N} and a plurality of compensation units 721₁-721_{N}. The correlators 720₁-720_{N} correspond to the analog-to-digital converters 71₁-71_{N} in the N analog-to-digital channels respectively, and the compensation units 721₁-721_{N} correspond to the correlators 720₁-720_{N}, respectively. Thus, the operations of one correlator 720ₓ and the corresponding compensation unit 721ₓ are performed for the corresponding analog-to-digital converter 71ₓ in one analog-to-digital channel, wherein 1≦X≦N. In the following, the embodiment will be described according to the input unit 70 and one analog-to-digital channel, such as the analog-to-digital channel of the analog-to-digital converter 71₁, the correlator 720₁, and the compensation unit 221₁.

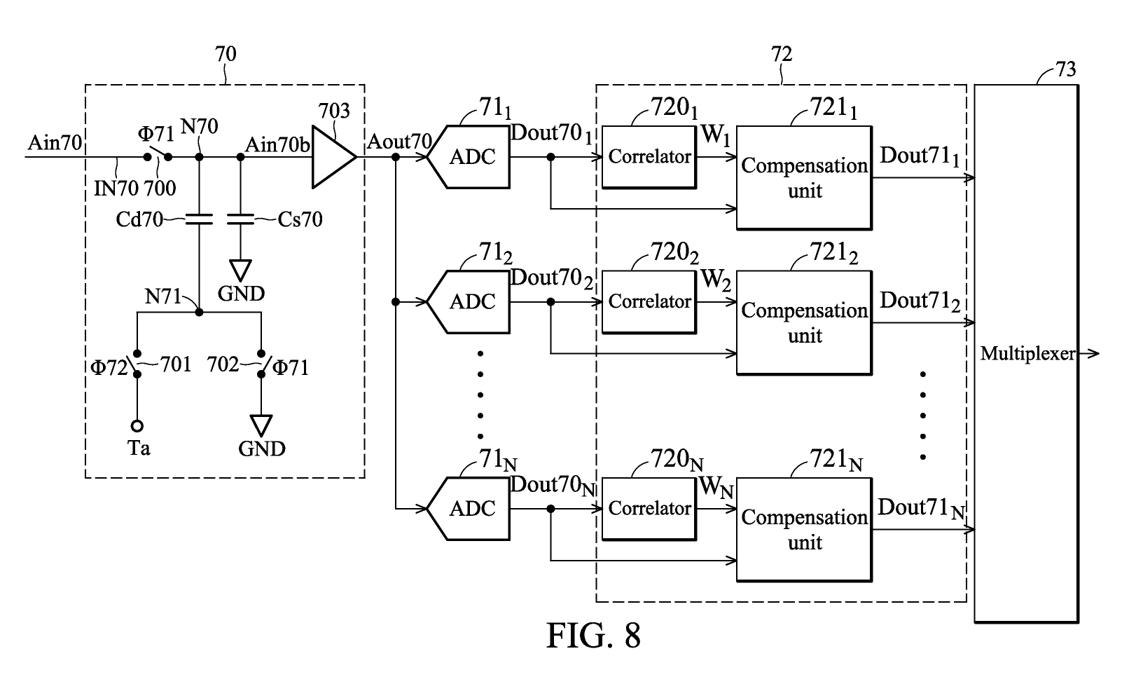

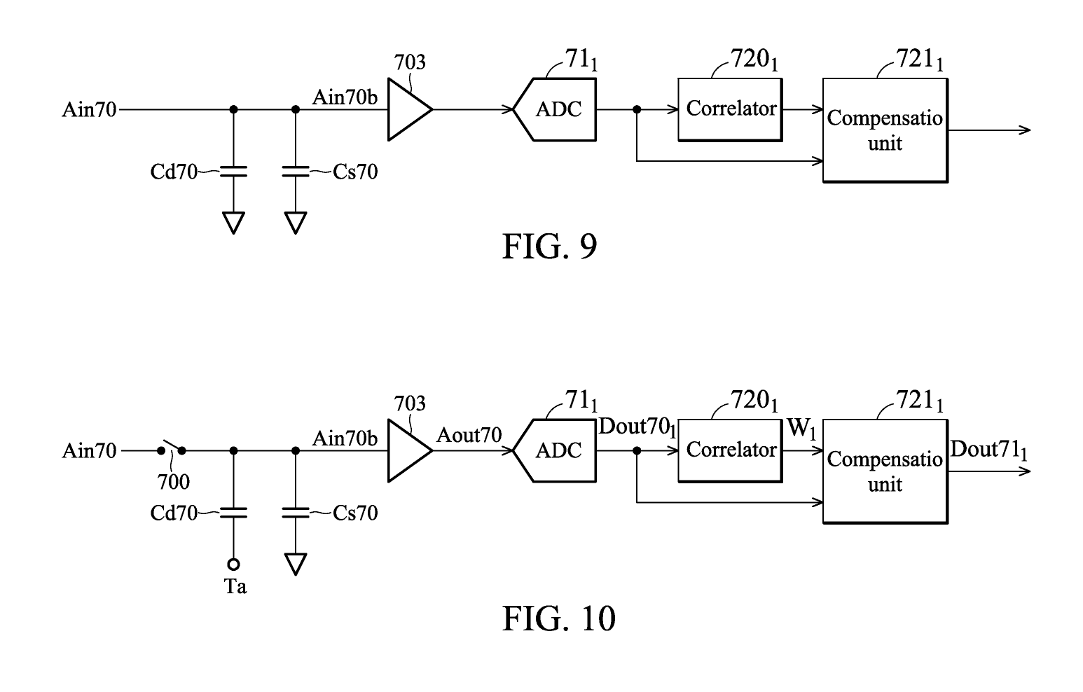

Referring to FIG. 9, during the tracking period, the control signal Φ71 is active, and the control signal Φ72 is inactive. The switches 700 and 702 are closed, and the switch 701 is open. The capacitors Cs70 and Cd70 sample the analog input signal Ain70. At this time, a signal Ain70b which is input to the buffer 703 is equal to the analog input signal Ain70. During the holding period, referring to FIG. 10, the control signal Φ71 is inactive, and the control signal Φ72 is active. The switches 700 and 702 are open, while the switch 701 is closed. The analog input signal Ain70 is blocked by the open switch 700, and the capacitor Cd70 is coupled to the first reference signal Ta. In the embodiment, the reference first signal Ta is equal to qₐ·R, wherein qₐ is a random sequence, and R is a constant and nonzero analog level. Hence, the signal Ain70b becomes related to the first reference signal Ta, represented by Equation (12).

$$Ain 70 b = Ain 70 - \frac{Cd 70}{Cs 70 + Cd 70} \times {q}_{a} \cdot R \qquad Equation ( 12 )$$

It is assumed that the buffer 703 is linear. The analog output signal Aout20 is represented by Equation (13).

$$\begin{matrix}Aout 70 = {g}_{bf} \times Ain 70 b + {o}_{bf} \\ = {g}_{bf} \times ( Ain 70 - \frac{Cd 70}{Cs 70 + Cd 70} \times {q}_{a} \cdot R ) + {o}_{bf}\end{matrix} \qquad Equation ( 13 )$$

g_{bf} represents the gain of the buffer 703, and o_{bf} represents the offset of the buffer 703. According to Equation (13), the analog output signal Aout70 is also related to the first reference signal Ta.

The analog-to-digital converter 71₁ receives and quantizes the analog output signal Aout70. In other words, the analog-to-digital converter 71₁ converts the analog output signal Aout70 to the digital output signals Dout70₁, represented by Equation (14).

Dout70₁=g_{ad}×Aout70+o_{ad} Equation (14)

g_{ad} represents the gain of the analog-to-digital converter 71₁, and o_{ad} represents the analog-to-digital converter 71₁.

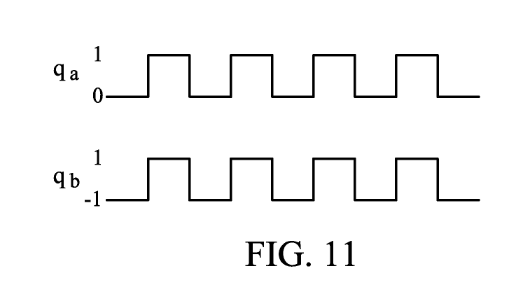

Since the analog output signal Aout70 is related to the first reference signal Ta, the digital output signals Dout70₁ converted from the analog output signal Aout70 is also related to the first reference signal Ta in the digital domain. As described above, the first reference signal Ta is equal to qₐ·R. In order to fine the terms of the digital output signals Dout70₁, which is related to the random sequence qₐ of the first reference signal Ta, the correlator 720₁ performs a correlation function to the digital output signals Dout70₁ and another reference signal comprising a random sequence q_{b} to extract the calibration parameter W₁ from the digital output signal Dout70₁, wherein the random sequence q_{b} is a zero-mean sequence and has the same waveform characteristics as the random sequence qₐ, an example of the random sequences qₐ, and q_{b} are as shown in FIG. 11. The correlation function is represented by Equation (15).

$$\begin{matrix}Corr \{ {q}_{b} , Dout {70}_{1} \} = E \{ {q}_{b} \times Dout {70}_{1} \} \\ = E \{ {q}_{b} \times ( {g}_{ad} \times Aout 70 + {o}_{ad} ) \} \\ = \overline{{q}_{a} \cdot {q}_{b}} \times {g}_{ad} \times {g}_{bf} \frac{cd 70}{cd 70 + Cs 70} \times R\end{matrix} \qquad Equation ( 15 )$$

If qₐ and q_{b} are binary-valued random sequences, q̅_̅{̅b̅}̅ ·̅q̅_̅{̅b̅}̅ is a known constant value. The remaining part

$${g}_{ad} \times {g}_{bf} \times \frac{Cd 70}{Cs 70 + Cd 70} \times R$$

serves as the calibration parameter W₁ for the digital output signals Dout70₁. The compensation unit 721₁ receives the calibration parameter W1 and calculates a ratio of a predetermined parameter and the calibration parameter W₁ to obtain a gain correction factor Gc₁. In this embodiment, the predetermined parameter is an ideal parameter W_{id} equal to

$$\frac{Cd 20}{Cd 20 Cs 20} \times R$$

(the term ‘ideal’ means being obviated from the gain mismatch issue). The gain correction factor Gc₁ is represented by Equation (16).

$$\begin{matrix}{Gc}_{1} = \frac{{W}_{id}}{{W}_{1}} \\ = \frac{\frac{Cd 70}{Cd 70 + Cs 70} \times R}{{g}_{ad} \times {g}_{bf} \frac{Cd 70}{Cd 70 + Cs 70} \times R} \\ = \frac{1}{{g}_{ad} \times {g}_{bf}}\end{matrix} \qquad Equation ( 16 )$$

The compensation unit 721₁ also receives the digital output signals Dout70₁ and multiplies the digital output signal Dout70₁ with the corresponding gain correction factor Gc₁ to obtain a final output signal Dout71₁, represented by Equation (17).

$$\begin{matrix}Dout {71}_{1} = {Gc}_{1} \times Dout {70}_{1} \\ = \frac{1}{{g}_{ad} \times {g}_{bf}} \times ( {g}_{ad} \times Aout 70 + {o}_{ad} ) \\ = \frac{1}{{g}_{ad} \times {g}_{bf}} \times [ {g}_{ad} \times ( {g}_{bf} \times Ain 70 {bo}_{bf} ) + {o}_{ad} ] \\ = Ain 70 b + {o}_{tot}\end{matrix} \qquad Equation ( 17 )$$

oₜₒₜ represents the total offset of the buffer 703 and the analog-to-digital converter 71₁.

According to Equation (17), the final output signal Dout71₁ is not related to the gain g_{bf} of the buffer 703 and the gain g_{ad} of the analog-to-digital converter 71₁. Thus, the gain mismatch errors of the analog-to-digital converter 71₁ do not affect the analog-to-digital conversion of the analog output signal Aout70.

The analog-to-digital converters 71₂-71_{N}, the correlators 720₂-720_{N}, and the compensation units 721₂-721_{N} perform the same operations respectively as the analog-to-digital converter 71₁, the correlator 720₁, and the compensation unit 721₁. Thus, the final output signals Dout71₂-Dout71_{N} are also not related to the gain of the buffer 703 and the gain of the respective analog-to-digital converter 71₂-71_{N}. Even if the gains of the analog-to-digital converters 71₁-71_{N} are different, there is no gain mismatch error among the digital output signals Dout70₁-Dout70_{N} in the N analog-to-digital channels. Please note that the compensation units 721₁-721_{N} aim to find a group of gain correction factors Gc that generate the same product when being multiplied by corresponding calibration parameter W (i.e. W₁×Gc₁=W₂×Gc₂= . . . =W_{N}×Gc_{N}). Therefore, the above-mentioned division function shown in Equation (16) shall be regarded as one embodiment rather than limitations of the present invention. Other algorithms that will generate substantially the same results shall also fall within the scope of the present invention.

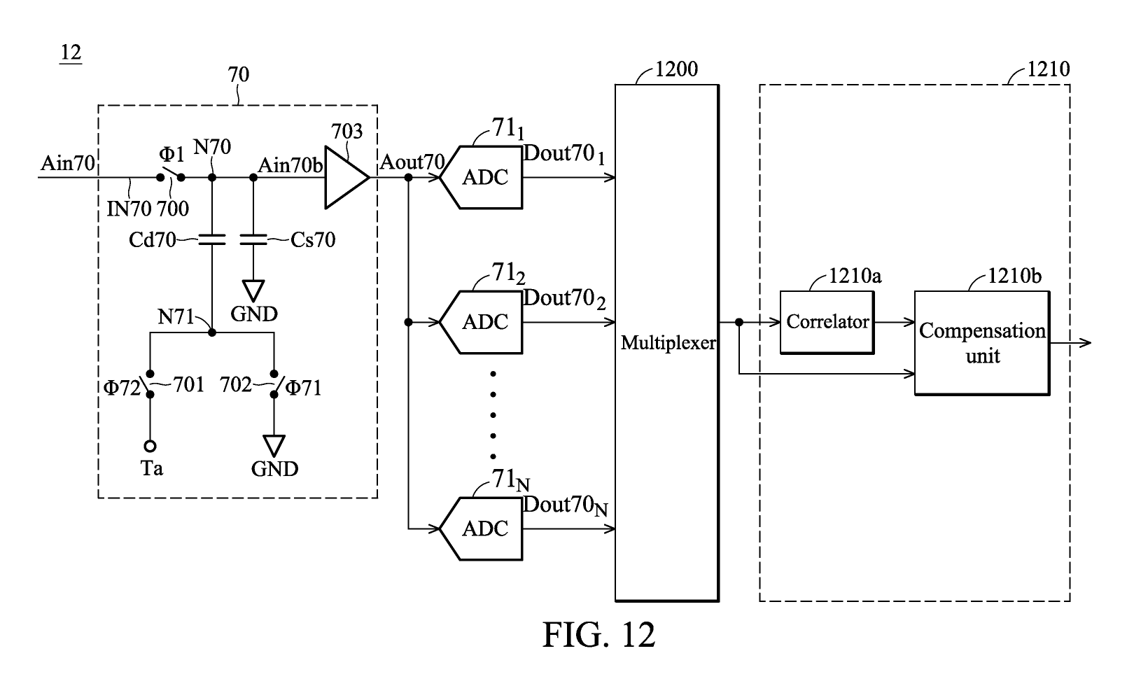

FIG. 12 shows another embodiment of an analog-to-digital conversion circuit 12 according to the present invention. Different from the analog-to-digital conversion circuit shown in FIG. 8, the digital output signals Dout70₁-Dout70_{N} in this embodiment are sent to a multiplexer 1200, and the output of the multiplexer 1200 is processed by a processing unit 1210 for gain mismatch compensation. Therefore, the processing unit 1210 may comprise only one correlator 1210a for performing correlation function and one compensation unit 1210b for performing calibration when the multiplexer 1200 has only one output. In other words, the analog-to-digital conversion circuit shown in FIG. 8 performs calibration prior to multiplexing, while the analog-to-digital conversion circuit in this embodiment performs multiplexing prior to the calibration.

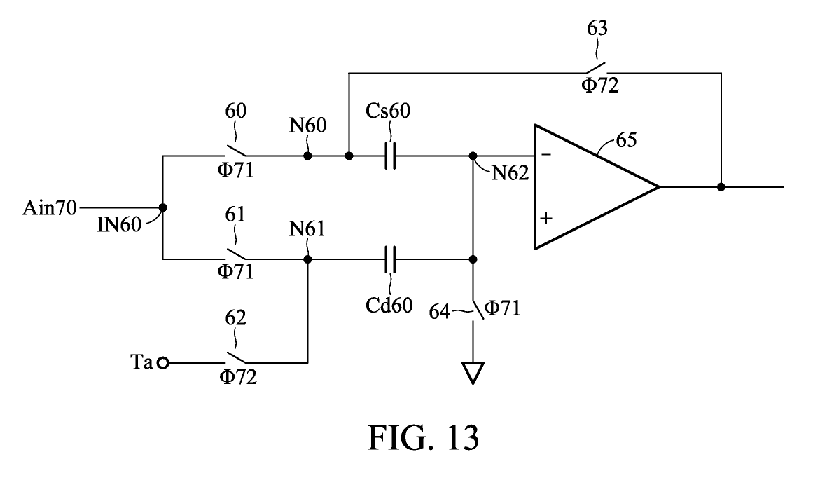

In the embodiments of FIG. 8 and FIG. 12, the input unit 70 is implemented by a track-and-hold amplifier. In some embodiment, the input unit 70 can be implemented by a sample-and-hold amplifier circuit, as shown in FIG. 13. Referring to FIG. 13, the sample-and-hold amplifier circuit comprises switches 60-64, capacitors Cs60 and Cd60, and an amplifier 65. An input node IN60 receives the analog input signal Ain70. The switch 60 is coupled between the input node IN60 and a node N60 and controlled by a control signal Φ71. The switch 61 is coupled between the input node IN60 and a node N61 and controlled by the control signal Φ71. The switch 62 has a first terminal coupled to the node N61 and a second terminal receiving the first reference signal Ta and controlled by a control signal Φ72, wherein an active period of the control signal Φ71 does not overlap an active period of the control signal Φ72. The capacitor Cs60 is coupled between the node N60 and a negative input terminal (−) of the amplifier 65, and the capacitor Cd60 is coupled between the node N61 and the negative input terminal (−) of the amplifier 65, wherein the negative input terminal (−) of the amplifier 65 is coupled to a node N62. The switch 63 is coupled between the node N60 and an output terminal of the amplifier 65 and controlled by the control signal Φ72. The switch 64 is coupled between the negative input terminal (−) of the amplifier 65 and a ground and controlled by the control signal Φ71.

During the sampling period, the control signal Φ71 is active, and the control signal Φ72 is inactive. The switches 60, 61, and 64 are closed, while the switches 62 and 63 are open. The capacitors Cs60 and Cd60 sample the analog input signal Ain70. During the holding period, the control signal Φ71 is inactive, and the control signal Φ72 is active. The switches 60, 61, and 64 are open, while the switches 62 and 63 are closed. The analog input signal Ain70 is blocked by the open switches 60 and 61, and the capacitor Cd60 is coupled to the first reference signal Ta. Thus, the amplifier 65 outputs the analog output signal Aout70 related to the first reference signal Ta and the analog input signal Ain70 to the analog-to-digital converter 71₁-71_{N}.

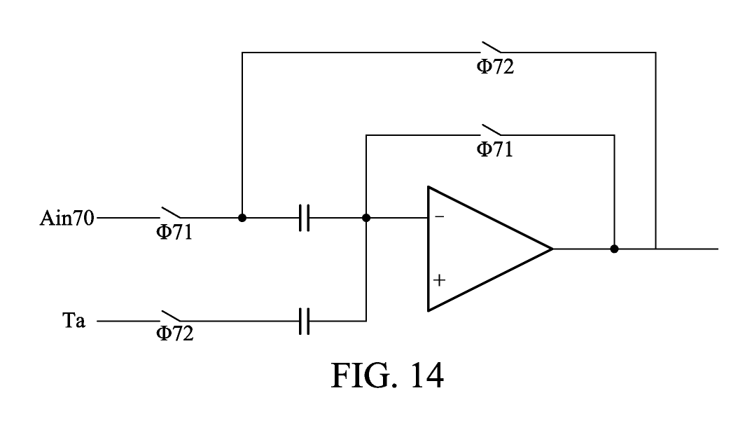

Please note that the sample-and-hold amplifier circuit shown in FIG. 13 is only an embodiment rather than a limitation of the present invention. The sample-and-hold amplifier circuit may be implemented by the structure shown in FIG. 14 in other embodiments. As long as the first reference signal Ta is injected into the sample-and-hold amplifier circuit, making the output of the sample-and-hold amplifier circuit be related to the first reference signal Ta, these modifications all fall within the scope of the present invention.

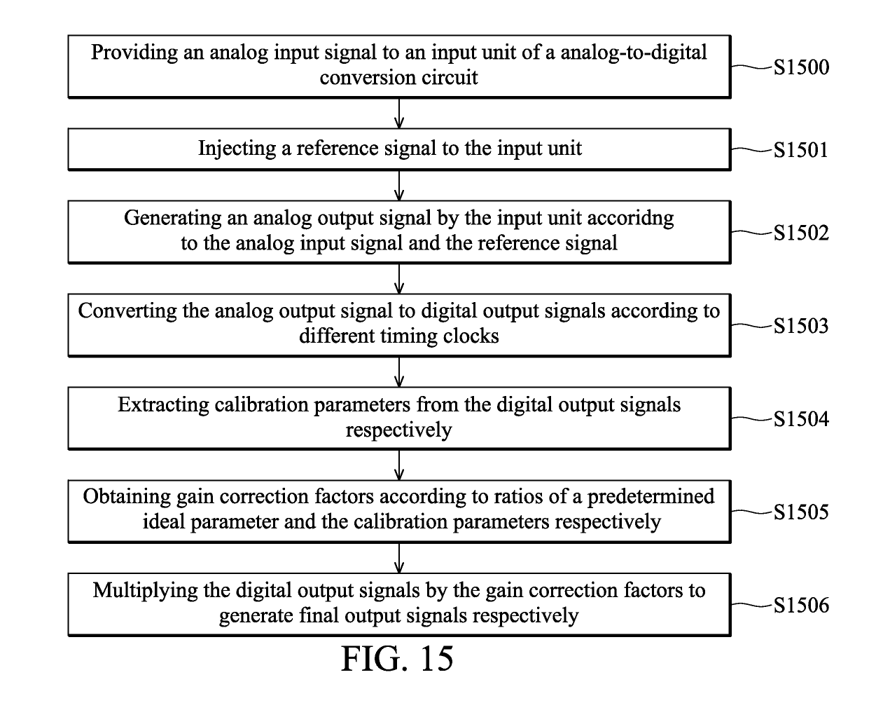

FIG. 15 is a flow chart of an exemplary embodiment of a method for calibrating an analog-to-digital conversion circuit to compensating errors such as gain mismatch among the analog-to-digital channels of the analog-to-digital conversion circuit. The method will be described with reference to FIGS. 15 and 8 and according to the input unit 70 and the analog-to-digital channel of the analog-to-digital converter 71₁, the correlator 720₁, and the compensation unit 721₁.

First, the analog input signal Ain70 is provided to the input unit 70 of the analog-to-digital conversion circuit 7 (step S1500), and the reference signal Ta is injected into the input signal 70 (step S1501). The analog output signal Aout70 is generated by the input unit 70 according to the analog input signal Ain70 and the reference signal Ta (step S1502). Thus, the analog output signal Aout70 is related to the reference signal Ta. The analog output signal Aout70 is converted to the digital output signals Dout70₁-Dout70_{N}, respectively, by the analog-to-digital converters 71₁-71_{N} according to different timing clocks (step S1503). The calibration parameters W₁-W_{N} are then extracted from the digital output signals Dout70₁-Dout70_{N} by the correlators 720₁-720_{N}, respectively (step S1504). Each of the calibration parameters W₁-W_{N} is related to the reference signal Ta, the gain of the buffer 703 of the input unit 70, and the gain of the respective analog-to-digital converter. The gain correction factors Gc₁-Gc_{N} are obtained according to the ratios of the predetermined ideal parameter W_{id} and the calibration parameters W₁-W_{N} by the compensation units 721₁-721_{N}, respectively (step S1505). Since the predetermined ideal parameter W_{id} is related to the reference signal Ta, each of the gain correction factors Gc₁-Gc_{N} generated by the ratios is only related to the gain of the input unit 70 and the gain of the corresponding analog-to-digital converter. Then, the digital output signals Dout70₁-Dout70_{N} are multiplied by the gain correction factors Gc₁-Gc_{N} to generate the final output signals Dout71₁-Dout71_{N} respectively (step S1506).

As described above, the final output signals Dout71₁-Dout71_{N} which are generated by multiplying the digital output signals Dout70₁-Dout70_{N} with the gain correction factors Gc₁-Gc_{N} are not related to the gain of the buffer 703 and the gain of the respective analog-to-digital converter 71₂-71_{N}. Even if the gains of the analog-to-digital converters 71₁-71_{N} are different, there is no gain mismatch error among the digital output signals Dout70₁-Dout70_{N} in the N analog-to-digital channels. The performance degradation problem and conversion nonlinearity problem faced by the conventional time-interleaved analog-to-digital conversion circuit are thereby solved. Moreover, because the time-interleaved analog-to-digital conversion circuits in above embodiments are background calibrated, the efficiency will not be sacrificed.

While the invention has been described by way of example and in terms of the preferred embodiments, it is to be understood that the invention is not limited to the disclosed embodiments. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. An analog-to-digital conversion circuit, comprising:
an input unit for receiving an analog input signal and outputting an analog output signal, wherein a first reference signal is injected into the input unit, and the analog output signal is related to the first reference signal;
at least one analog-to-digital converter, for receiving the analog output signal and converting the analog output signal to a digital output signal; and
a processing unit for receiving the digital output signal and performing correlation computation on the digital output signal with a second reference signal to generate a calibration parameter.

2. The analog-to-digital conversion circuit as claimed in claim 1, wherein the processing unit further obtains a gain correction factor according to a ratio of a predetermined parameter and the calibration parameter and compensates for gain mismatch error of the digital output signal by the gain correction factor.

3. The analog-to-digital conversion circuit as claimed in claim 1, wherein the input unit comprises a track-and-hold amplifier circuit or a sample-and-hold amplifier circuit.

4. The analog-to-digital conversion circuit as claimed in claim 1, wherein the input unit comprises:
an input node for receiving the analog input signal;
a first switch coupled between the input node and a first node and controlled by a first control signal;
a first capacitor coupled between the first node and a second node;
a second switch having a first terminal coupled to second node and a second terminal receiving the first reference signal and controlled by a second control signal, wherein an active period of the first control signal does not overlap an active period of the second control signal;
a third switch coupled between the second node and a third node and controlled by the first control signal; and
a second capacitor coupled between the first node and the third node.

5. The analog-to-digital conversion circuit as claimed in claim 1, wherein the input unit comprises:
an input node for receiving the analog input signal;
an amplifier having at least one input terminal and at least one output terminal;
a first switch coupled between the input node and a first node and controlled by a first control signal;
a second switch coupled between the input node and a second node and controlled by the first control signal;
a third switch having a first terminal coupled to the second node and a second terminal receiving the first reference signal and controlled by a second control signal, wherein an active period of the first control signal does not overlap an active period of the second control signal;
a first capacitor coupled between the first node and the input terminal of the amplifier;
a second capacitor coupled between the second node and the input terminal of the amplifier;
a fourth switch (63) coupled between the first node and the output terminal of the amplifier and controlled by the second control signal; and
a fifth switch coupled between the input terminal of the amplifier and a ground and controlled by the first control signal.

6. The analog-to-digital conversion circuit as claimed in claim 1, wherein the first reference signal comprises a random sequence.

7. The analog-to-digital conversion circuit as claimed in claim 6, wherein the random sequence has a constant and nonzero mean.

8. The analog-to-digital conversion circuit as claimed in claim 1, wherein the second reference signal comprises a random sequence and has a same waveform characteristic as the first reference signal.

9. The analog-to-digital conversion circuit as claimed in claim 8, wherein the random sequence has a zero mean.

10. The analog-to-digital conversion circuit as claimed in claim 2, wherein the processing unit comprises:
a correlator for receiving the digital output signal, performing the correlation computation on the digital output signal and the second reference signal to generate the calibration parameter; and
a compensation unit for receiving the calibration parameter and obtaining a gain correction factor according to a ratio of a predetermined parameter and the calibration parameter;
wherein the compensation unit multiplies the digital output signal and the gain correction factor for calibrating the digital output signal and generates a corresponding final output signal.

11. The analog-to-digital conversion circuit as claimed in claim 1, comprising a plurality of analog-to-digital converters each for receiving the analog output signal and converting the analog output signal to a digital output signal, and implemented as a time-interleaved analog-to-digital conversion circuit.

12. The analog-to-digital conversion circuit as claimed in claim 11, wherein the processing unit receives the digital output signals from the analog-to-digital converters, performs correlation computation on the digital output signals and the second reference signal, extracts calibration parameters, compensates for errors of the digital output signals according to the calibration parameters, and generates a plurality of final output signals after the compensation, and the analog-to-digital conversion circuit further comprises a multiplexer for receiving the final output signals and selectively outputting at least one of the final output signals.

13. A time-interleaved analog-to-digital conversion circuit with background calibration, comprising:
an input unit for receiving an analog input signal and outputting an analog output signal, wherein a reference signal is injected into the input unit, and the analog output signal is related to the reference signal and the analog input signal;
a plurality of analog-to-digital converters, for receiving the analog output signal and respectively converting the analog output signal to digital output signals according to a plurality of timing clocks; and
a processing unit for receiving at least one of the digital output signals, and extracting a calibration parameter for analog-to-digital conversion gain compensation according to the digital output signal.

14. The analog-to-digital conversion circuit as claimed in claim 13, wherein the input unit comprises:
an input node for receiving the analog input signal;
a first switch coupled between the input node and a first node and controlled by a first control signal;
a first capacitor coupled between the first node and a second node;
a second switch having a first terminal coupled to second node and a second terminal receiving the reference signal and controlled by a second control signal, wherein an active period of the first control signal does not overlap an active period of the second control signal;
a third switch coupled between the second node and a third node and controlled by the first control signal; and
a second capacitor coupled between the first node and the third node.

15. The analog-to-digital conversion circuit as claimed in claim 13, wherein the input unit comprises:
an input node for receiving the analog input signal;
an amplifier having at least one input terminal and at least one output terminal;
a first switch coupled between the input node and a first node and controlled by a first control signal;
a second switch coupled between the input node and a second node and controlled by the first control signal;
a third switch having a first terminal coupled to the second node and a second terminal receiving the reference signal and controlled by a second control signal, wherein an active period of the first control signal does not overlap an active period of the second control signal;
a first capacitor coupled between the first node and the input terminal of the amplifier;
a second capacitor coupled between the second node and the input terminal of the amplifier;
a fourth switch coupled between the first node and the output terminal of the amplifier and controlled by the second control signal; and
a fifth switch (64) coupled between the input terminal of the amplifier and a ground.

16. The analog-to-digital conversion circuit as claimed in claim 13, wherein the reference signal comprises a random sequence.

17. A method for calibrating an analog-to-digital conversion circuit, comprising:
providing an analog input signal and a first reference signal;
generating an analog output signal according to the analog input signal and the first reference signal;
converting the analog output signal into at least one digital output signal; and
performing a correlation computation on the digital output signal to generate a calibration parameter.

18. The method as claimed in claim 17, further comprising compensating for gain mismatch error of the digital output signal according to the calibration parameter.

19. The method as claimed in claim 18, wherein the step of compensating for the gain mismatch error of the digital output signal according to the calibration parameter comprises:
obtaining a gain correction factor according to a ratio of a predetermined parameter and the calibration parameter, wherein the calibration parameter is related to the first reference signal, and a gain of the analog-to-digital conversion circuit; and
compensating for the gain mismatch error of the digital output signal by the gain correction factor.

20. The method as claimed in claim 19, wherein the step of compensating for the gain mismatch error of the digital output signal by the gain correction factor comprises:
multiplying the digital output signal with the gain correction factor to generate corresponding final output signal.

21. The method as claimed in claim 20, wherein the final output signal is not related to the gain of the analog-to-digital conversion circuit.

22. The method as claimed in claim 17, wherein the step of generating the analog output signal according to the analog input signal and the first reference signal comprises:
injecting the first reference signal into the analog input signal to generate a modified analog input signal; and
generating the analog output signal according to the modified analog input signal.

23. The method as claimed in claim 22, wherein the step of injecting the first reference signal into the analog input signal comprises:
coupling the analog input signal to a first terminal of a capacitor; and
coupling the first reference signal to a second terminal of the capacitor.
